(19) United States
(12) Patent Application Publication
(10) Pub. No.: US 2016/0035891 A1
(43) Pub. Date: Feb. 4, 2016

(54) STRESS IN N-CHANNEL FIELD EFFECT TRANSISTORS

(71) Applicant: QUALCOMM Incorporated, San Diego, CA (US)

(72) Inventors: Jeffrey Junhao XU, San Diego, CA (US); Kern RIM, San Diego, CA (US); Stanley Seungchul SONG, San Diego, CA (US); Choh Fei YEAP, San Diego, CA (US)

(21) Appl. No.: 14/448,548

(22) Filed: Jul. 31, 2014

(51) Int. Cl. H01L 29/78; H01L 29/66

(52) U.S. Cl. CPC H01L 29/7843; H01L 29/785; H01L 29/66795

(57) ABSTRACT

A fin field-effect transistor (FinFET) includes a gate stack on a surface of a semiconductor fin. The semiconductor fin may include a capping material and a stressor material. The stressor material is confined by the capping material to a region proximate the gate stack. The stressor material provides stress on the semiconductor fin proximate the gate stack.

### BACKGROUND

1. Field

Aspects of the present disclosure relate to semiconductor devices, and more particularly to conductive gate stressors for fin field effect transistor (FinFET) structures.

2. Background

Strain engineering for field effect transistor (FET) performance has been reviewed as an alternative to reducing gate oxide thickness. In planar FET geometries, imparting a strain in semiconductor chip regions, such as the source and drain regions of a FET, is an approach used in the related art. In some FET, (e.g., fin field effect transistor (FinFET)) structures, however, the volume of the fin available for strain engineering is small. In addition, the compressive strain that is beneficial for P-channel (e.g., hole charge carriers) FinFETs is detrimental to the N-channel (e.g., electron charge carriers) FinFETs. The volume and compressive strain issues have limited the ability to use strain engineering in N-channel FinFET devices.

### SUMMARY

A method for fabricating a fin field effect transistor (FinFET) device on a semiconductor substrate may include forming a gate stack on a surface of a semiconductor fin. This method also includes depositing a dielectric layer on the semiconductor fin to be substantially coplanar with a surface of a conductive gate of the gate stack. The method may also include recessing the conductive gate to be below a level of the dielectric layer. Further, the method may include depositing a stressor material onto a recessed surface of the conductive gate and the dielectric layer and confining the stressor material. The method also includes changing a volume of the stressor material to stress the semiconductor fin proximate the conductive gate.

A fin field effect transistor (FinFET) may include a gate stack on a surface of a semiconductor fin and a capping material. The fin field effect transistor also includes a stressor material confined by the capping material to a region proximate the gate stack to provide stress on the semiconductor fin proximate the gate stack.

A fin field effect transistor (FinFET) may include a gate stack on a surface of a semiconductor fin and a capping material. This fin field effect transistor also includes means for applying stress to the gate stack. The stress applying means may be confined by the capping material to a region proximate the gate stack to provide stress on the semiconductor fin proximate the gate stack.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer in an aspect of the present disclosure.

FIG. 2 illustrates a cross-sectional view of a die in accordance with an aspect of the present disclosure.

FIG. 3 illustrates a cross-sectional view of a metal-oxide-semiconductor field-effect transistor (MOSFET) device in an aspect of the present disclosure.

FIG. 4 illustrates a transistor in accordance with an aspect of the present disclosure.

FIG. 5A is an exemplary schematic of a fin of a fin field effect transistor (FinFET) illustrating compressive and tensile stress.

FIG. 5B illustrates a schematic of a fin field effect transistor (FinFET) indicating various stress components along dimensions of a fin of the FinFET.

FIG. 6 is an exemplary graph illustrating stress induced electron mobility variations caused by the application of stress components, T_{fL}, T_{fH} and T_{fW}, along the dimensions of the fin.

FIG. 7 is an exemplary graph illustrating stress induced hole mobility variations caused by the application of stress components, T_{fL}, T_{fH} and T_{fW}, along the dimensions of the fin.

FIG. 8 illustrates an example of a FinFET architecture including a stressor material applied along a height of the fin according to aspects of the present disclosure.

FIGS. 9A-9G illustrate cross sectional views and corresponding top-down views of exemplary processing to provide an N-channel FinFET metal gate stressor according to aspects of the present disclosure.

FIGS. 10A-10B illustrate cross sectional views and corresponding top-down views of exemplary processing to provide an N-channel FinFET metal gate stressor according to aspects of the present disclosure.

FIGS. 11A-11B illustrate cross sectional views and corresponding top-down views of exemplary processing to provide an N-channel FinFET metal gate stressor according to aspects of the present disclosure.

FIG. 12 illustrates a method for fabricating a fin field effect transistor (FinFET) device on a semiconductor substrate.

FIG. 13 is a block diagram showing an exemplary wireless communication system 900 in which an aspect of the disclosure may be advantageously employed.

FIG. 14 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Semiconductor fabrication processes are often divided into three parts: a front end of line (FEOL), a middle of line (MOL) and a back end of line (BEOL). Front end of line processes include wafer preparation, isolation, well formation, gate patterning, spacers, and dopant implantation. A middle of line process includes gate and terminal contact formation. The gate and terminal contact formation of the middle of line process, however, is an increasingly challenging part of the fabrication flow, particularly for lithography patterning. Back end of line processes include forming interconnects and dielectric layers for coupling to the FEOL devices. These interconnects may be fabricated with a dual damascene process using plasma-enhanced chemical vapor deposition (PECVD) deposited inter-layer dielectric (ILD) materials.

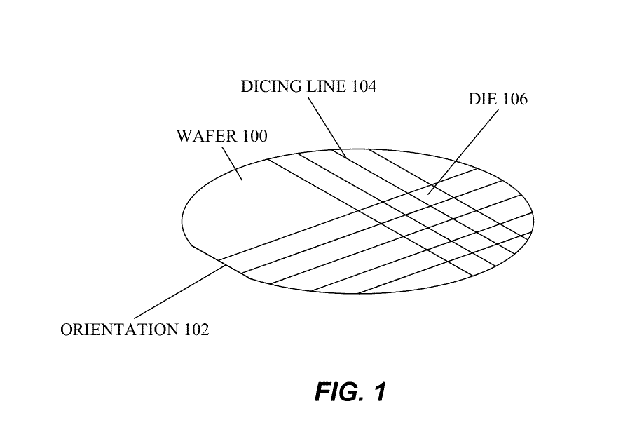

FIG. 1 illustrates a perspective view of a semiconductor wafer in an aspect of the present disclosure. A wafer 100 may be a semiconductor wafer, or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a compound material, such as gallium arsenide (GaAs) or gallium nitride (GaN), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and l, which are the Miller indices for a plane (hkl) in the crystal. Each index denotes a plane orthogonal to a direction (h, k, l) in the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to l. For some crystals, negative numbers are used (written as a bar over the index number) and for some crystals, such as gallium nitride, more than three numbers may be employed to adequately describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

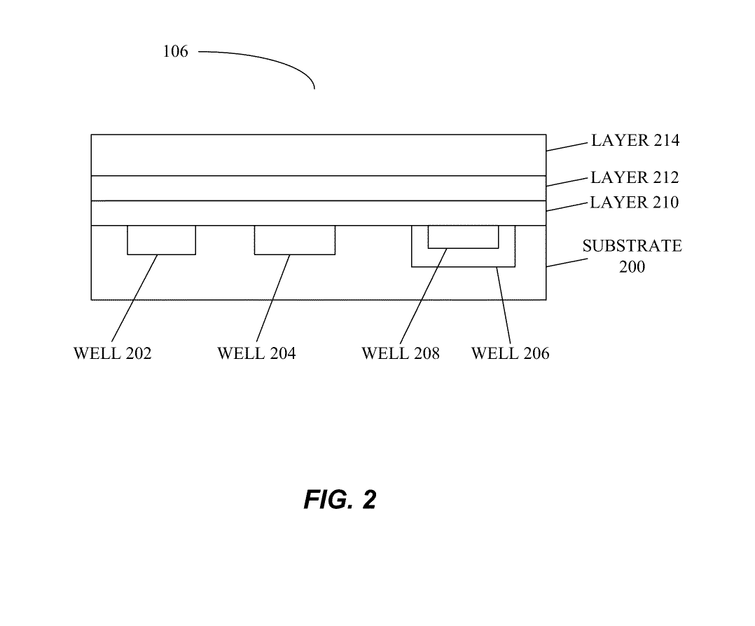

FIG. 2 illustrates a cross-sectional view of a die 106 in accordance with an aspect of the present disclosure. In the die 106, there may be a substrate 200, which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within a substrate 200 (e.g., a semiconductor substrate), there may be wells 202 and 204, which may be the source and/or drain of a field-effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have wells 206 and 208. The well 208 may be completely within the well 206, and, in some cases, may form a bipolar junction transistor (BJT). The well 206 may also be used as an isolation well to isolate the well 208 from electric and/or magnetic fields within the die 106.

Layers 210 through 214 may be added to the die 106. The layer 210 may be, for example, an oxide or insulating layer that may isolate the wells 202-208 from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers 210 and 214. The layer 214 may be an encapsulating layer, which may protect the layers 210 and 212, as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers 210-214. For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers 210-214, and through selective removal, material selection, and dopant concentration of the substrate 200 and the wells 202-208, many different structures and electronic devices may be formed within the scope of the present disclosure.

Further, the substrate 200, the wells 202-208, and the layers 210-214 may be selectively removed or added through various processes. Chemical wet etching, chemical mechanical planarization (CMP), plasma etching, photoresist masking, damascene processes, and other methods may create the structures and devices of the present disclosure.

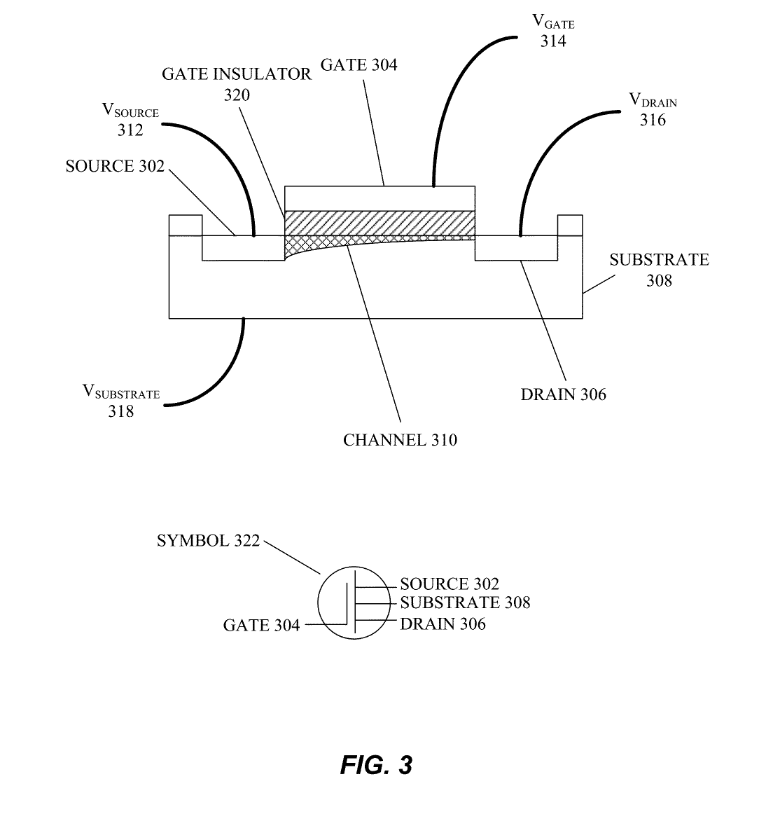

FIG. 3 illustrates a cross-sectional view of a metal-oxide-semiconductor field-effect transistor (MOSFET) device 300 in an aspect of the present disclosure. The MOSFET device 300 may have four input terminals. The four inputs are a source 302, a gate 304, a drain 306, and a substrate 308. The source 302 and the drain 306 may be fabricated as the wells 202 and 204 in the substrate 308, or may be fabricated as areas above the substrate 308, or as part of other layers on the die 106. Such other structures may be a fin or other structure that protrudes from a surface of the substrate 308. Further, the substrate 308 may be the substrate 200 on the die 106, but substrate 308 may also be one or more of the layers 210-214 that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314 or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide, or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For p-type MOSFETs (using holes as charge carriers in the channel 310), an arrow is applied to the substrate 308 terminal in the symbol 322 pointing toward the gate 304 terminal.

The gate 304 may also be made of different materials. In some designs, the gate 304 is made from polycrystalline silicon, also referred to as polysilicon or poly, which is a conductive form of silicon. Although referred to as “poly” or “polysilicon” herein, metals, alloys, or other electrically conductive materials are contemplated as appropriate materials for the gate 304 as described in the present disclosure.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304 terminal. Although referred to as “metal,” polycrystalline materials, alloys, or other electrically conductive materials are contemplated as appropriate materials for the gate 304 as described in the present disclosure.

To interconnect to the MOSFET device 300, or to interconnect to other devices in the die 106 (e.g., semiconductor), interconnect traces or layers are used. These interconnect traces may be in one or more of layers 210-214, or may be in other layers of the die 106.

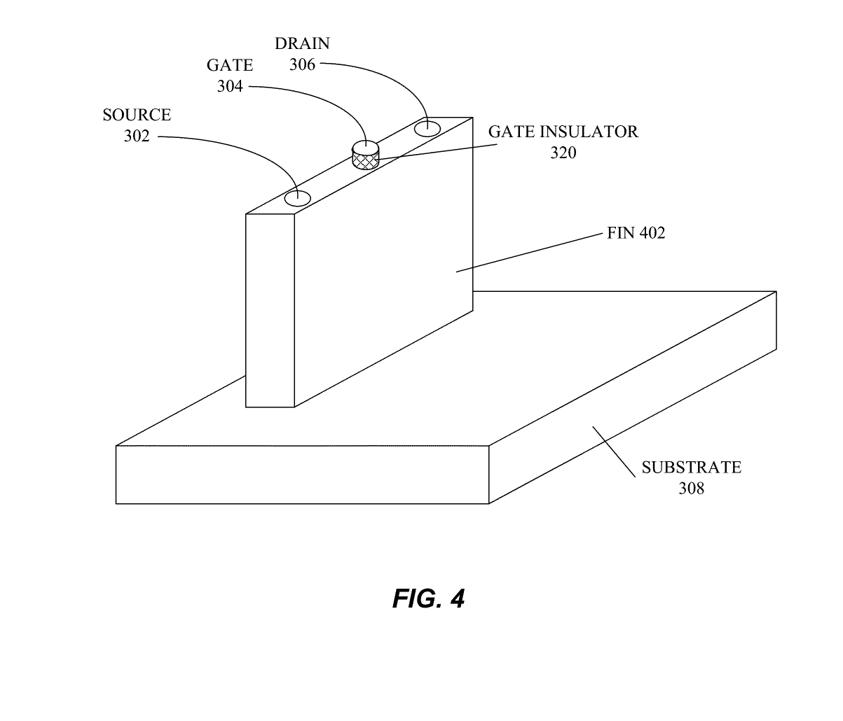

FIG. 4 illustrates a transistor in accordance with an aspect of the present disclosure. A fin-structured FET (FinFET 400) operates in a similar fashion to the MOSFET device 300 described with respect to FIG. 3. A fin 402 in a FinFET 400, however, is grown or otherwise coupled to the substrate 308. The fin 402 includes the source 302, the gate 304, and the drain 306. The gate 304 is coupled to the fin 402 through the gate insulator 320. In a FinFET structure, the physical size of the FinFET 400 may be smaller than the MOSFET device 300 structure shown in FIG. 3. This reduction in physical size allows for more devices per unit area on the die 106.

A high mobility conduction channel is desirable for high performance transistors. Material selection and strain engineering are design features that may alter the mobility of charge carriers (e.g., electrons and holes) in the channel of transistors. Strain engineering is used in MOSFETs. In fin-based structures (e.g., FinFETs), however, the use of strained materials is challenging. In particular, there are more free surfaces in FinFET structures. As a result, the source/drain volume available for strain engineering is small compared to other FET geometries and techniques.

Stressors or materials subject to strain may be applied to terminals of the FinFET to increase the mobility of the conduction channel. For example, source and drain stressors have been applied to complementary metal oxide semiconductors (CMOS) to enhance performance. The source and drain stressors may be based on different stressor techniques such as dislocation stress memorialized technique (DSMT). For example, a DSMT may be implemented by dislocation of a semiconductor device material (e.g., silicon) of the fin. The planar N-channel or N-type metal-oxide-semiconductor (NMOS) source/drain stressor, however, may not be applicable to an N-channel FinFET because the N-channel FinFET lacks a large silicon base.

### Stress in N-Channel Field Effect Transistors

Aspects of the present disclosure are directed to strain induced carrier mobility enhancement in FinFETs (e.g., N-channel FinFET). In one aspect of the disclosure, strain induced carrier mobility for the FinFET is improved by applying stress (e.g., compressive stress or tensile stress) along a height of the fin. While compressive stress along the fin length is an effective technique for mobility enhancement in the P-channel FinFET, significant carrier (e.g., electron) mobility enhancement is achieved by applying compressive stress along the fin height direction. A FinFET architecture may include a gate stack formed on a surface of the fin (e.g., semiconductor fin). The gate stack may include a conductive gate and a corresponding dielectric (e.g., high K dielectric) and a spacer to create separation between the conductive gate and the high K dielectric, and other elements (e.g., inter-layer dielectric) of the FinFET architecture.

The compressive stress may be applied to one or more surfaces of the gate along the height of the fin. To apply the compressive stress, a dielectric layer (e.g., a first inter-layer dielectric) is deposited on the semiconductor fin. The first dielectric layer may be processed (e.g., etched or planarized) so that a first surface (e.g., level) of the first dielectric layer is substantially coplanar (e.g., flush) with a surface of the conductive gate. The conductive gate is then recessed so that the surface of the conductive gate is below the level of the first dielectric layer.

In one aspect of the disclosure, a stressor material is deposited on the recessed surface of the conductive gate and the first dielectric layer to apply compressive stress on the conductive gate. For example, the stressor material may be deposited in an opening defined by the recessed surface of the conductive gate and side walls of the first dielectric layer. The stressor material may include tungsten (W), titanium (Ti), cobalt (Co), silicon (Si), nickel (Ni), polysilicon, perovskite (CaTiO3), or other like material.

In some aspects, the spacer may also be deposited between the first dielectric and the recessed portion to provide separation between the stressor material and the first dielectric. In some aspects of the disclosure, the stressor material is deposited on the first surface of the first dielectric layer and in the recessed portion so that the stressor material is on a different level than the planarized surface. In this aspect, the stressor material is processed (e.g., etched or planarized) to remove the stressor material on the first dielectric layer. The stressor material is also processed to remove portions of the stressor material that are aligned with the recessed portion so that a surface of the stressor material opposite the conductive gate is substantially coplanar with the first surface of the first dielectric layer.

A capping material may be deposited on the first surface of the first dielectric and the surface of the stressor material opposite the conductive gate to confine the stressor material. The capping material may include a dielectric material (e.g., a polysilicon or an oxide). In one aspect of the present disclosure, a volume of the stressor material may be changed (e.g., increased) to stress the semiconductor fin proximate the conductive gate. For example, compressive stress may be applied to the conductive gate due to volume expansion resulting from a disruptive structural phase transition of the stressor material.

In one aspect of the disclosure, the volume expansion may be induced by a millisecond anneal process or other process including ultra violet cure induced volume expansion. The volume of the stressor material may also be expanded by silicidation or oxidation of the stressor material to compress the conductive gate. For example, the volume of the stressor material may be increased to compressively stress the semiconductor fin in an N-channel FinFET or to provide tensile stress on the semiconductor fin in a P-channel FinFET.

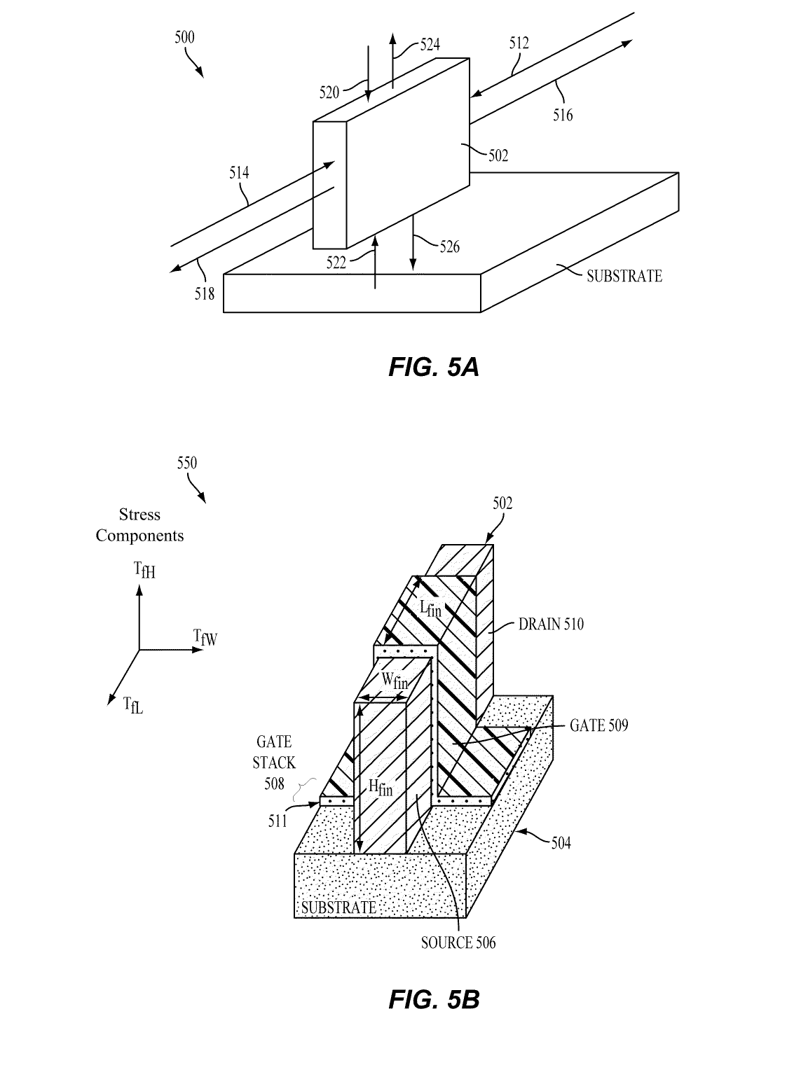

As noted, carrier (e.g., electron and/or hole) mobility is enhanced by imparting compressive or vertical stress along the height of the fin (T_{fH}). For example, a stressor material confined by a capping material may be positioned in a region in close proximity to the gate stack where the stressor material provides a stress on the semiconductor that is proximate to the gate stack, as illustrated in FIGS. 5A-5B.

FIG. 5A is an exemplary schematic of a fin of a FinFET 500 illustrating compressive and tensile stress. For example, compressive stress along the length of a fin 502 is illustrated by arrows 512 and 514 directed toward the fin and indicating the application of compressive stress pushing toward the fin in opposite directions along the length of the fin. Similarly, compressive stress along the height of the fin 502 is illustrated by arrows 520 and 522. Tensile stress along the length of the fin 502 may be illustrated by arrows 516 and 518. In this example, the arrows 516 and 518 are directed away from the fin, indicating the application of tensile stress that pulls away from the fin in opposite directions along the length of the fin. Similarly, tensile stress along the height of the fin 502 is illustrated by arrows 524 and 526. Although the description is directed to the application of stress applied along the width, length and height of the fin, the stress can be applied in different directions. For example, the stress can be applied in multiple directions away from an x, y or z axis, such that the applied stress includes a combination of tensile and/or compressive stress components along the x, y and z axis. The application of compressive stress and/or tensile stress to the fin may result in mobility variations based on the stress components in different directions as illustrated by the schematic of FIG. 5B.

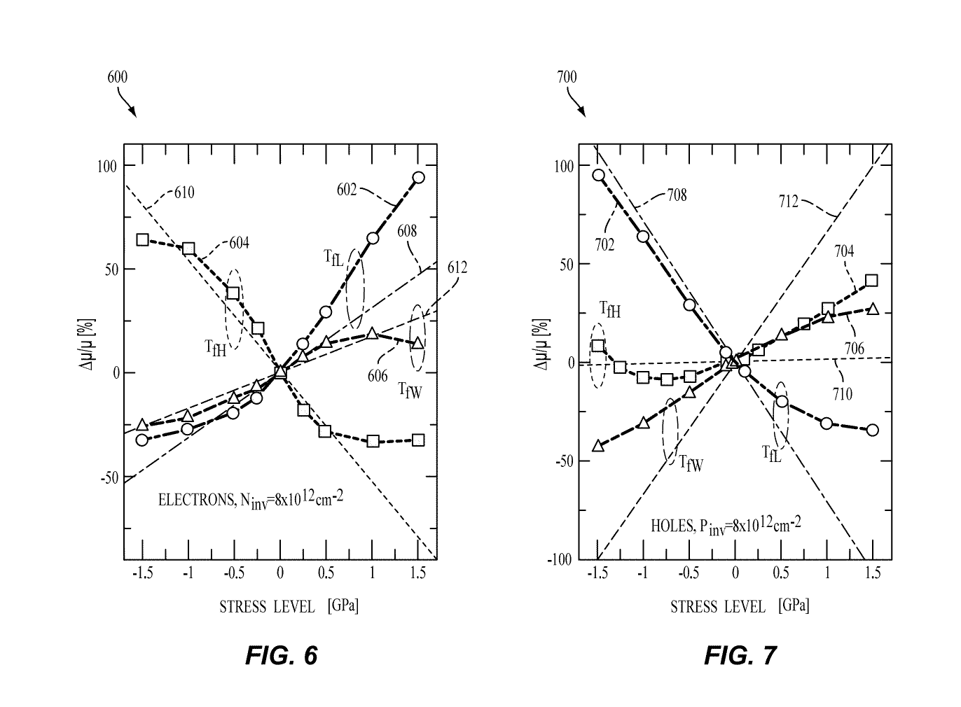

FIG. 5B illustrates a schematic of a FinFET 550 indicating various stress components along dimensions of a fin 502 of the FinFET 500. The fin 502 of the FinFET 500 may be grown or otherwise coupled to a substrate. The substrate 504 may be a silicon substrate or other like supporting layer, for example, comprised of an oxide layer, a nitride layer, a metal oxide layer or a silicon layer. The fin 502 includes a source 506, a gate stack 508, and a drain 510. The gate stack 508 includes a gate 509 and a gate insulator 511. The gate stack 508 may be coupled to the fin 502 through the gate insulator 511. Various stress components may be applied to portions of the fin corresponding to the gate stack 508. For example, the stress components correspond to stress (e.g., compressive and/or tensile stress) applied along dimensions of the fin corresponding to the gate stack 508. A height, Hfin, a width, Wfin, and a length, Lfin, represent the dimensions of the fin. The stress components along the dimensions include stress components in the fin height direction, T_{fH}, stress components in the fin width direction, T_{fW}, and stress components in the fin length direction, T_{fL}. The mobility variations versus the stress components, T_{fL}, T_{fH} and T_{fW} are illustrated in FIGS. 6 and 7.

FIGS. 6 and 7 are exemplary graphs illustrating stress induced electron and hole mobility variations.

Regarding FIG. 6, an exemplary graph 600 illustrates stress induced electron mobility variations caused by the application of stress components, T_{fL}, T_{fH} and T_{fW}, along the dimensions of the fin 502. The y-axis of FIG. 6 represents stress induced electron mobility variation. The stress induced electron mobility variation is represented as a ratio of a change in the electron mobility (Δμ) when the stress is applied versus the electron mobility (μ) without the stress. The x-axis of FIG. 6 represents stress level (e.g., compressive and/or tensile stress level) and is represented by units of pressure (e.g., giga pascal (GPa)). For example, stress levels below zero represent compressive stress while stress levels above zero represent tensile.

Electron mobility variations of the stress components are illustrated in conjunction with a model of the electron mobility variations of the stress components. The stress components, including T_{fL} 602, T_{fH} 604 and T_{fW} 606, are represented by thick dashed lines, respectively, while the corresponding model of the stress components, including T_{fL} 608, T_{fH} 610 and T_{fW} 612, are represented by thin dashed lines, respectively.

Regarding FIG. 7, an exemplary graph 700 illustrates stress induced hole mobility variations of each of the stress components, T_{fL}, T_{fH} and T_{fW}, along the dimensions of the fin 502. The y-axis of FIG. 7 corresponds to the stress induced hole mobility variation represented as a ratio of a change in the hole mobility (Δμ) when the stress is applied versus the hole mobility (μ) without the stress. The x-axis of FIG. 7 corresponds to the stress level (e.g., compressive stress level) and is represented by units of pressure (e.g., giga pascal (GPa)). Similar to the illustration in FIG. 6, stress levels of FIG. 7 that are below zero represent compressive stress while stress levels above zero represent tensile stress.

Carrier mobility (e.g., electron mobility of FIG. 6 and hole mobility of FIG. 7) variations of the stress components are illustrated in conjunction with a model of the carrier mobility variations of the stress components. In FIG. 6, the stress components, including T_{fL} 602, T_{fH} 604 and T_{fW} 606, are represented by thick dashed lines, respectively, while the corresponding model of the stress components, including T_{fL} 608, T_{fH} 610 and T_{fW} 612, are represented by thin dashed lines, respectively. Similarly, the stress components, including T_{fL} 702, T_{fH} 704 and T_{fW} 706 of FIG. 7, are represented by thick dashed lines, respectively, while the corresponding model of the stress components, including T_{fL} 708, T_{fH} 710 and T_{fW} 712, are represented by thin dashed lines, respectively.

Regarding FIG. 6, for example, when tensile stress is induced along the length of the fin 502, electron mobility is enhanced as shown by the tensile stress component, (e.g., T_{fL} 602) and corresponding model of the tensile stress component (e.g., T_{fL} 608). For example, when T_{fL} 602 (e.g., the tensile stress component) is increased to 1.5 GPa, the corresponding increase in the stress induced electron mobility variation is above seventy-five percent.

Similarly, when compressive stress is induced along the height of the fin 502, electron mobility is enhanced as shown by the compressive stress component, (e.g., T_{fH} 604) and corresponding model of the compressive stress component (e.g., T_{fH} 610). For example, when the compressive stress component (e.g., T_{fH} 604) is increased to −1.5 GPa, the corresponding increase in the stress induced electron mobility variation is above fifty percent. Thus, electron mobility enhancement is achieved by applying compressive stress along a height, T_{fH,} of the FinFET.

Hole mobility enhancement is also achieved by applying compressive stress along a height, T_{fH}, of the FinFET, as illustrated in FIG. 7. Applying compressive stress along the height of the fin (T_{fH}), however, slightly enhances hole mobility, relative to the enhancement in hole mobility achieved by inducing compressive stress along T_{fL} or the electron mobility enhancement achieved when compressive stress is induced (See FIG. 6 illustration) along the height of the fin (T_{fH}). For example, when compressive stress is induced along the length of the fin 502, hole mobility is enhanced as shown by the compressive stress component, (e.g., T_{fL} 702) and corresponding model of the compressive stress component (e.g., T_{fL} 708). Thus, when the compressive stress component (e.g., T_{fL} 702) is increased to −1.5 GPa, the corresponding increase in the stress induced electron mobility variation is above seventy-five percent. When compressive stress component (e.g., T_{fH} 704) is increased to −1.5 GPa, however, the corresponding increase in the stress induced electron mobility variation is below twenty-five percent.

Stress components may be induced in different directions based on a desired carrier mobility for an implementation. For example, in some implementations different combinations of stress components may be induced to enhance carrier mobility. For example, to improve electron mobility in an N-channel FinFET, tensile stress may be induced along the length T_{fL} of the fin 502 in conjunction with inducing compressive stress along the height T_{fH} of the of the fin 502. For example, when T_{fL} 602 (e.g., the tensile stress component) is increased to 1.5 GPa, the corresponding increase in the stress induced electron mobility variation is above seventy-five percent, as shown in FIG. 6. Similarly, when the compressive stress component (e.g., T_{fH} 604) is increased to −1.5 GPa, the corresponding increase in the stress induced electron mobility variation is above 50 percent.

Some P-channel FinFET implementations may induce tensile stress along the height, T_{fH} of the fin 502 rather than compressive stress, because of the improvement in hole mobility when tensile stress is induced relative to the hole mobility achieved by inducing compressive stress along the height of the fin 502. For example, inducing tensile stress of 1.5 GPa along the height of the fin 502 increases hole mobility variation to above 25, as shown by the stress component, T_{fH} 704. The increase in hole mobility variation when compressive stress along the height of the fin to −1.5 GPa, however, is below 25 percent.

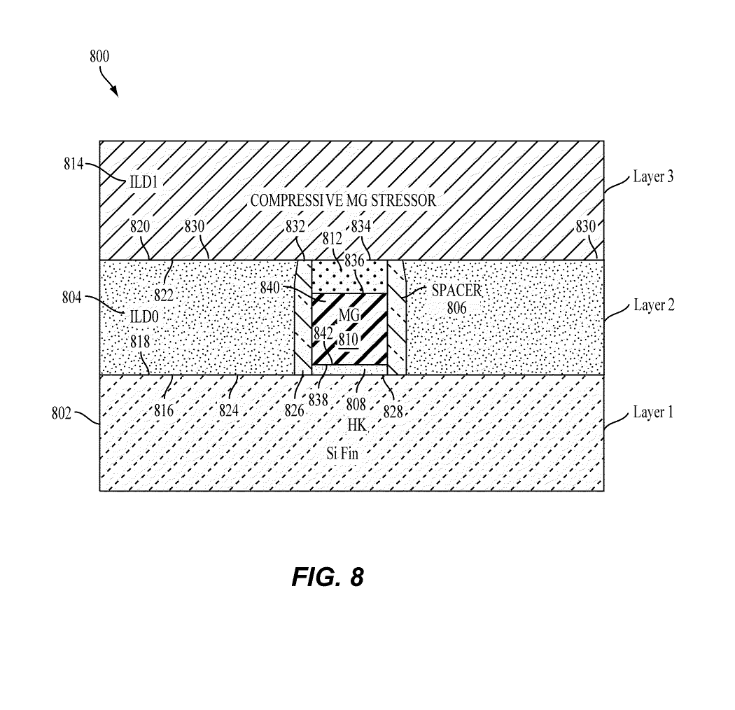

FIG. 8 illustrates an example of a FinFET architecture 800 including a stressor material applied along a height of the fin according to aspects of the present disclosure. In one aspect of the disclosure, the FinFET may be an N-channel FinFET. The FinFET architecture includes a fin 802, a first inter-layer dielectric 804, a spacer 806, a high K dielectric 808, a conductive gate (MG) 810 (e.g., metal gate), stressor material (e.g., a compressive metal gate stressor) 812 and a second inter-layer dielectric 814 or capping material. In one aspect of the disclosure, the material of the fin 802 includes silicon. The compressive conductive gate stressor 812 may be an N-channel metal gate stressor. The compressive conductive gate stressor 812 may be characterized by a disruptive structural phase transition with volume expansion property when subject to a spike thermal anneal, volume expansion with oxidation, or volume expansion with silicidation.

In one aspect of the disclosure, the FinFET architecture may include multiple layers coupled together. For example, the fin 802 may be positioned within or form a first layer (layer 1) of the FinFET architecture 800 while the second inter-layer dielectric 814 is positioned within or forms a third layer (layer 3) of the FinFET architecture 800. In some aspects, the first inter-layer dielectric 804, the spacer 806, the high K dielectric 808, the metal gate (MG) 810, and the compressive conductive gate stressor 812 may be positioned within one or more layers. For example, the first inter-layer dielectric 804, the spacer 806, the high K dielectric 808, the metal gate (MG) 810, and the compressive conductive gate stressor 812 may be positioned within or form a second layer (layer 2) of the FinFET architecture 800. The first layer of the FinFET architecture may be coupled to the third layer via the second layer. For example, the second layer of the FinFET architecture may be between the first layer and the third layer. In this case, a first surface 816 of the second layer may be on a surface 818 of the first layer and a second surface 820 of the second layer may be on a surface 822 of the third layer.

In some implementations, the surface 818 of the first layer corresponds to a first surface of the fin 802. The first surface 816 of second layer corresponds to a first surface 824 of the first inter-layer dielectric 804, a first surface 826 of the spacer 806 and a first surface 828 of the high K dielectric 808. Similarly, the surface 822 of the third layer corresponds to a first surface of the second inter-layer dielectric 814. The second surface 820 of the second layer corresponds to a second surface 830 of the first inter-layer dielectric 804, a second surface 832 of the spacer 806 and a first surface 834 of the compressive conductive gate stressor 812. In this implementation, the first surface 816 of the second layer is opposite the second surface 820 of the second layer.

In some implementations, the metal gate 810 may be positioned between the compressive conductive gate stressor 812 and the high K dielectric 808. In this implementation, first surface 836 and the second surface 838 of the metal gate 810 are coupled to or positioned on a second surface 840 of the compressive metal gate stressor and a second surface 842 of the high K dielectric 808. The spacer 806 may separate the first inter-layer dielectric 804 from the high k dielectric 808. In this configuration, the metal gate and the compressive conductive gate stressor 812 protect the high k dielectric 808 and the metal gate stack from chemical interaction with the first inter-layer dielectric 804 and oxide filled shallow trench isolation.

In this configuration, the compressive metal gate stressor is formed on the N-channel metal gate so that compressive stress due to volume expansion resulting from a disruptive structural phase transition is applied along a height of the fin or applied to the first surface 836 of the metal gate 810. The N-channel FinFET metal gate stressor has a high stress level (e.g., >1.5 GPa) to boost electron mobility. The electron mobility may be boosted up to seventy five percent. Other benefits of the N-channel FinFET stressor include a reduction in the cost of fabrication relative to other stressors such as a silicon carbide (SiC) source/drain or strain relaxed substrate (SRB) stressor.

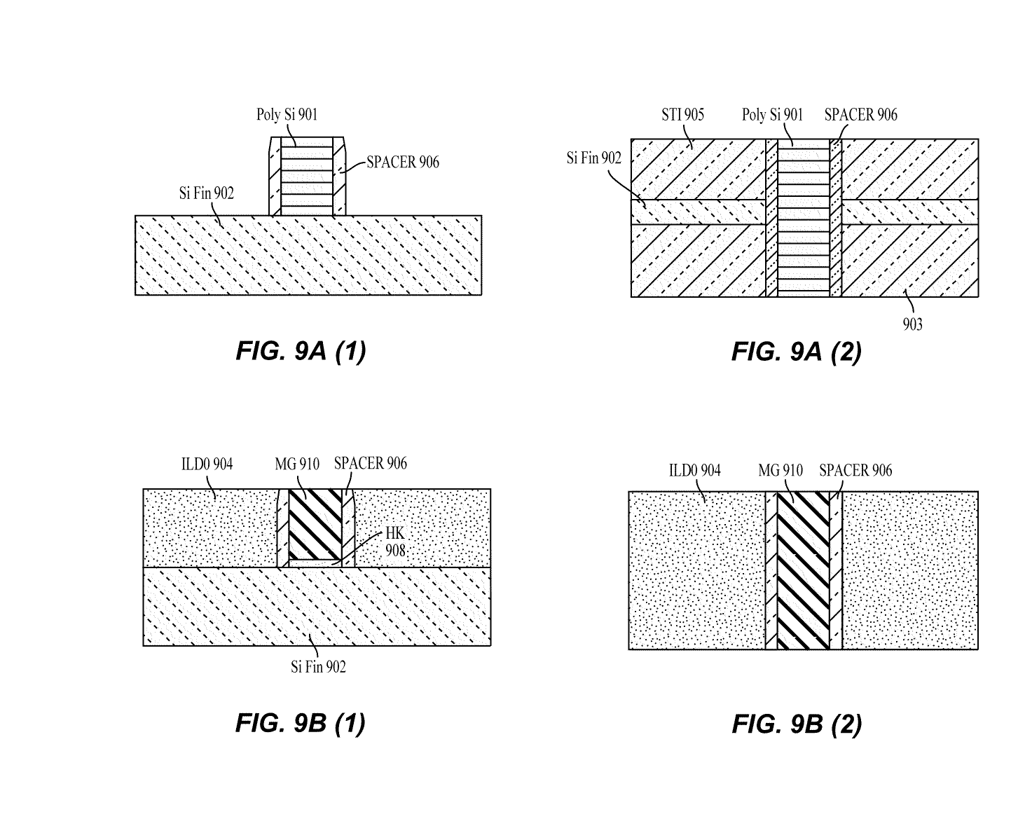

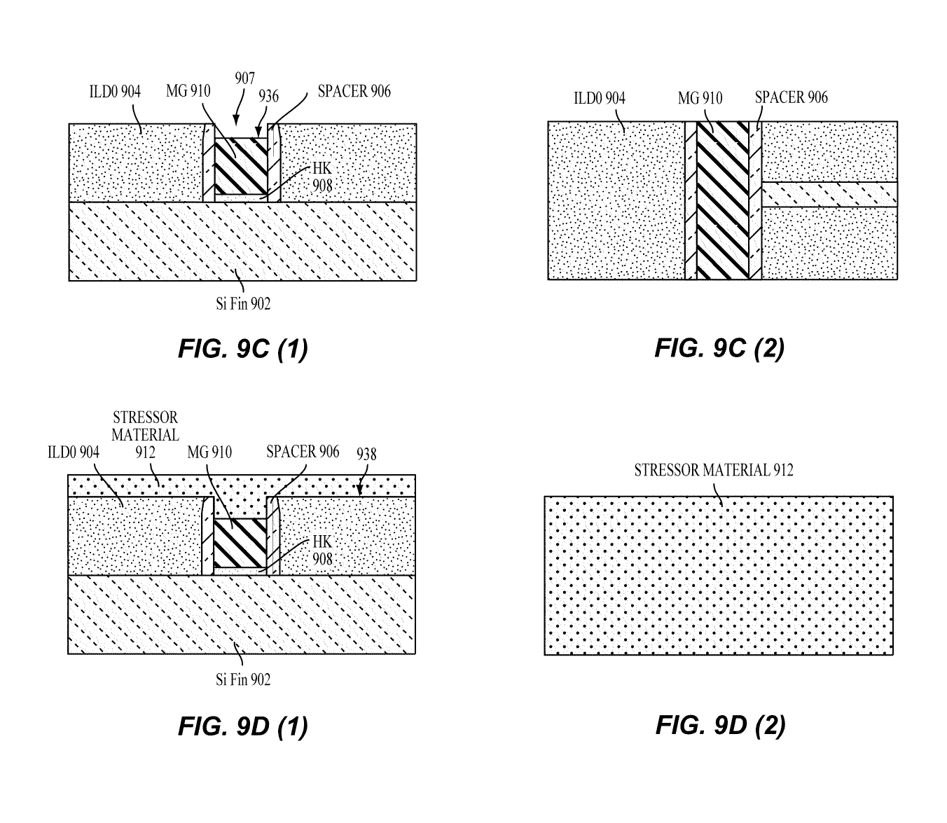

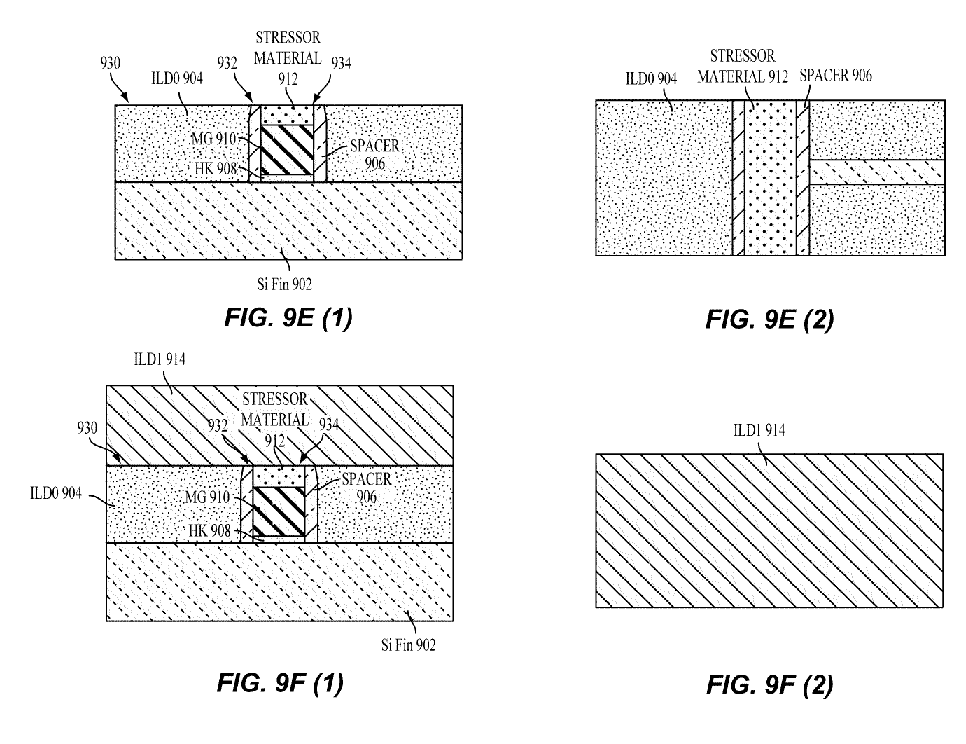

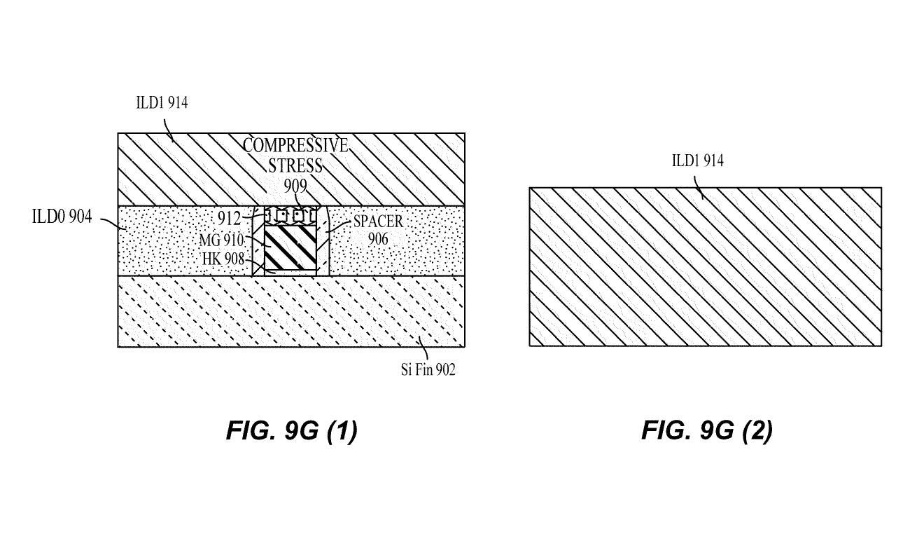

FIGS. 9A-9F illustrate cross sectional views (1) along a fin of the FinFET and corresponding top-down views (2) of exemplary processing to provide an N-channel FinFET metal gate stressor according to aspects of the present disclosure. In the implementation of FIGS. 9A-9F, the capping layer includes an inter-layer dielectric such that the compressive metal gate stressor is characterized by a disruptive structural phase transition with volume expansion property when subject to a spike thermal anneal.

In the cross sectional view (1) and corresponding top-down view (2) of FIG. 9A, a spacer 906 is formed on a fin 902 according to spacer formation technique and a polysilicon layer 901 is patterned between the spacer 906. The fin 902 may be deposited on a substrate 903 (or wafer) after the formation of the spacer 906. The substrate 903 may include a shallow trench isolation (STI) region 905.

In the cross sectional view (1) and corresponding top-down view (2) of FIG. 9B, a first inter-layer dielectric 904 is deposited on the fin 902 in conjunction with a process of smoothing surfaces with the combination of chemical and mechanical forces such as a chemical mechanical planarization (CMP) process. The first inter-layer dielectric 904 deposition and the CMP process may be followed by a replacement process, such as a high K/metal gate process. The replacement process may be performed to replace the polysilicon layer 901 with a metal gate 910 and a high K dielectric 908 that couples the metal gate 910 to the fin 902.

In the cross sectional view (1) and corresponding top-down view (2) of FIG. 9C, a portion of the metal gate 910 may be etched according to a metal gate recess etch process to define a recess 907 between the spacer 906 and a surface 936 of the metal gate 910.

In the cross sectional view (1) and corresponding top-down view (2) of FIG. 9D, a stressor material 912 is deposited on a surface 938 of the first inter-layer dielectric 904 and in the recess 907. The stressor material 912 may be subjected to a disruptive structural phase transition with volume expansion property when where is thermal anneal spike in temperature.

In the cross sectional view (1) and corresponding top-down view (2) of FIG. 9E, a process of smoothing one or more surfaces of the stressor material 912 is implemented. The smoothing process may include the combination of chemical and mechanical forces such as the CMP. The smoothing process may be implemented to planarize or remove portions of the stressor material 912 outside of the recess. In some implementations, the stressor material 912 is planarized such that a surface 934 of the stressor material 912 opposite the metal gate 910 is flush with a surface 930 of the first inter-layer dielectric 904 and a surface 932 of the spacer.

In the cross sectional view (1) and corresponding top-down view (2) of FIG. 9F, a capping material such as a second inter-layer dielectric 914 is deposited on the surface 934 of the stressor material 912, the surface 930 of the first inter-layer dielectric 904 and the surface 932 of the spacer. The capping material (e.g., second inter-layer dielectric 914) confines the stressor material.

In the cross sectional view (1) and corresponding top-down view (2) of FIG. 9G, compressive stress illustrated by arrows 909 along the fin height direction is illustrated. The compressive stress may be due to volume expansion resulting from a disruptive structural phase transition. The volume expansion resulting from the disruptive structural phase transition may be caused by a millisecond thermal anneal process using laser or flash anneal. The stressor material 912 may include perovskite (CaTiO₃). The compressive stress along the fin height direction may be generated by a phase transition from a room temperature orthorhombic (Pbnm) structure to a tetragonal polymorph at a temperature in a range of 1100-1150 OC with a volume expansion due to larger lattice constant of the tetragonal structure. In this implementation, a lateral structure of the stressor material 912 changes while the chemical structure remains the same.

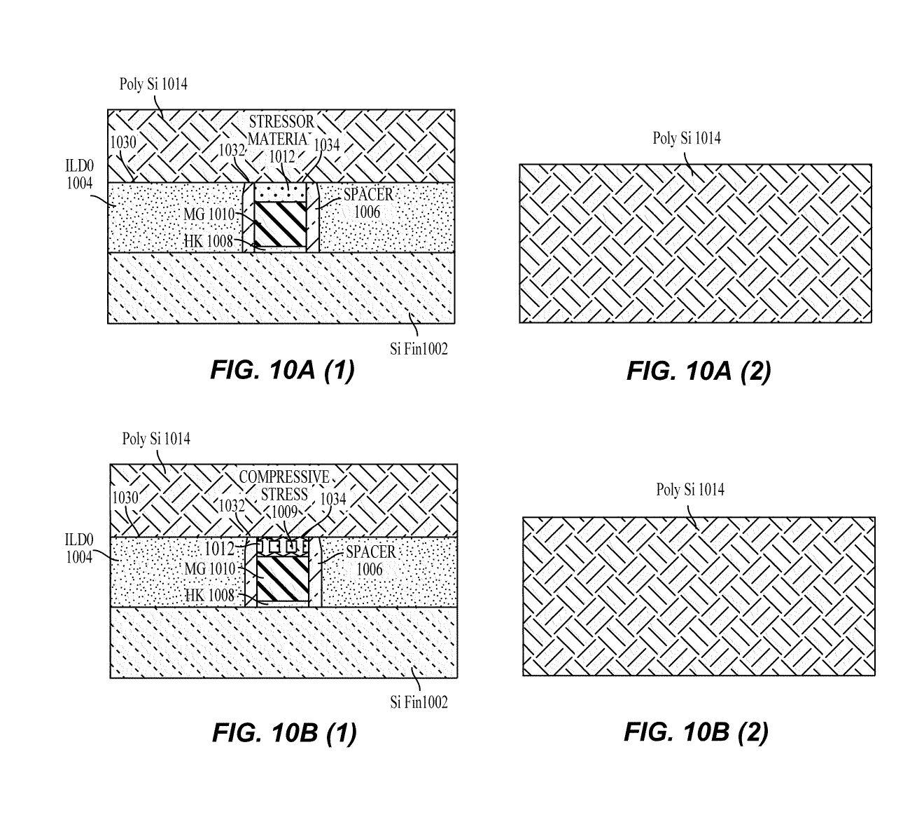

FIGS. 10A-10B illustrate cross sectional views (1) along a fin of the FinFET and corresponding top-down views (2) of exemplary processing to provide an N-channel FinFET metal gate stressor according to aspects of the present disclosure. In the implementation of FIGS. 10A-10B, the capping layer includes polysilicon capping layer 1014 such that a stressor material 1012 is characterized volume expansion with silicidation. For example, silicon diffuses into the stressor material to create the increase in volume.

In the cross sectional view (1) and corresponding top-down view (2) of FIG. 10A, a polysilicon capping layer 1014 is deposited on a surface 1034 of the stressor material 1012, a surface 1030 of a first inter-layer dielectric 1004 and a surface 1032 of a spacer 1006. In this implementation, silicon (e.g., from the polysilicon capping layer 1014) diffuses into the stressor material to create more material in the stressor, thus more volume.

In the cross sectional view (1) and corresponding top-down view (2) of FIG. 10B, compressive stress illustrated by arrows 1009 applied along the fin height direction is illustrated. The compressive stress may be due to volume expansion with silicidation. In this case, the volume expansion may be caused by a millisecond thermal anneal process using laser or flash anneal. The stressor material 1012 may include tungsten (W), titanium (Ti), cobalt (Co) or nickel (Ni). A volume of the stressor material 1012 expands during silicidation to form a silicide such as tungsten silicide (WSi), titanium silicide (TiSi), cobalt silicide (CoSi) or nickel silicide (NiSi). The compressive stress along the fin height direction may be generated by the silicide (e.g., tungsten silicide (WSi), titanium silicide (TiSi), cobalt silicide (CoSi) or nickel silicide (NiSi)) confined in space by the polysilicon capping layer 1014.

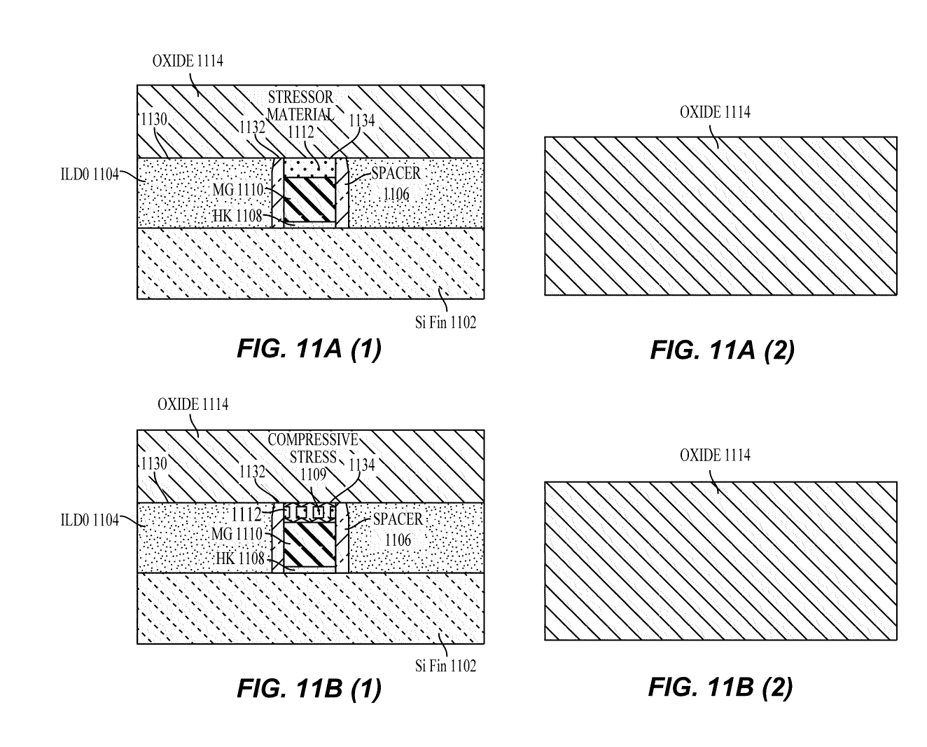

FIGS. 11A-11B illustrate cross sectional views (1) along a fin of the FinFET and corresponding top-down views (2) of exemplary processing to provide an N-channel FinFET metal gate stressor according to aspects of the present disclosure. In the implementation of FIGS. 11A-11B, the capping layer includes an oxide layer 1114 such that a stressor material 1112 is characterized by volume expansion with oxidation.

In the cross sectional view (1) and corresponding top-down view (2) of FIG. 11A, a capping layer (e.g., the oxide layer 1114) is deposited on a surface 1134 of the stressor material 1112, a surface 1130 of a first inter-layer dielectric 1104 and a surface 1132 of a spacer 1106. In this implementation, the stressor material 1112 is oxidized to create more volume. The oxidization of the stressor material may be based on the oxide in the oxide layer 1114.

In the cross sectional view (1) and corresponding top-down view (2) of FIG. 11B, compressive stress illustrated by arrows 1109 applied along the fin height direction is illustrated. The compressive stress may be due to volume expansion with oxidation. In one aspect, the stressor material may be subject to a low temperature (e.g., <400° C.) to convert the stressor material (e.g., polysilicon stressor material) into an oxide to generate the compressive stress. When the stressor material is polysilicon, the stressor material may be converted into a silicon oxide (SiO₂). In this case, the compressive stress along the fin height direction may be generated by the silicon oxide confined in a space by the oxide layer 1114.

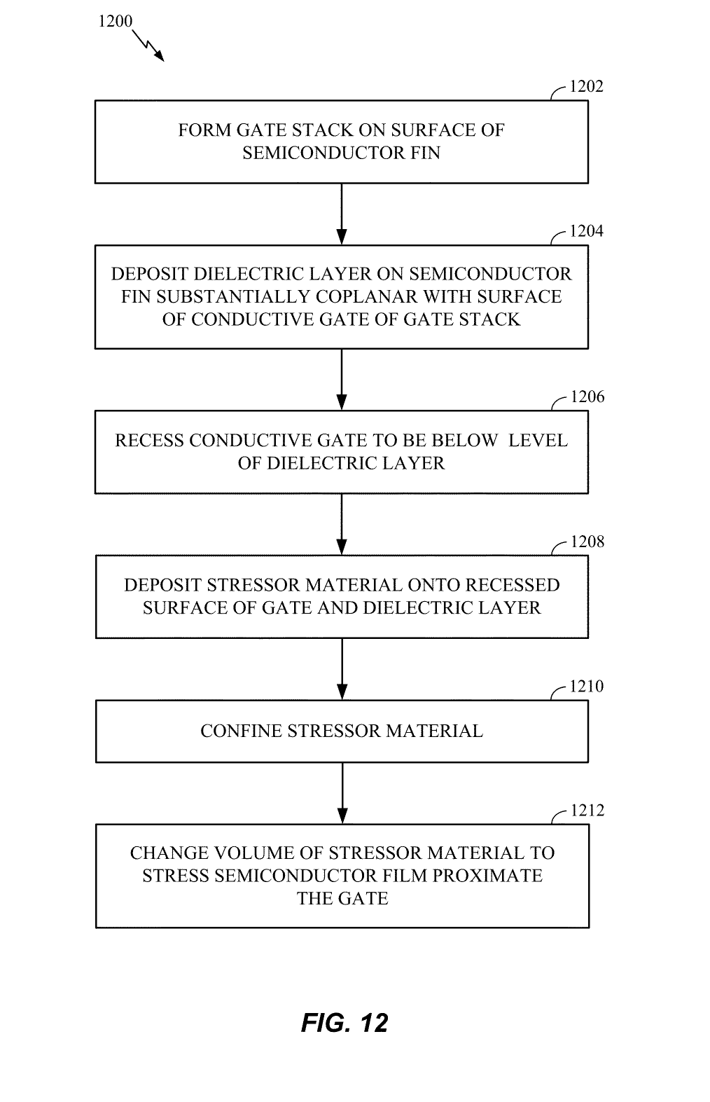

FIG. 12 illustrates a method 1200 for fabricating a fin field effect transistor (FinFET) device on a semiconductor substrate. In block 1202, a gate stack is formed on a surface of a semiconductor fin (e.g., fin 802, 902, 1002, 1102). The gate stack may include a high K dielectric (e.g., the high K dielectric 808), a spacer (e.g., the spacer 806) and a conductive gate (e.g., metal gate 810). In block 1204, a dielectric layer (e.g., the first inter-layer dielectric 1104) is deposited on the semiconductor fin. The dielectric layer is deposited on the semiconductor fin so that it is substantially coplanar or flush with a surface of the conductive gate of the gate stack. In block 1206, the conductive gate is recessed to a level that is below a level of the dielectric layer. For example, the dielectric layer is recessed to define an opening between the recessed portion of the dielectric layer, the spacer and the metal gate. In block 1208, a stressor material (e.g., stressor material 1112) is deposited onto a recessed surface of the conductive gate the dielectric layer or spacers coupled to the dielectric layer. In block 1210, the stressor material is confined by a capping material (e.g., the oxide layer 1114). In block 1212, a volume of the stressor material is changed to stress the semiconductor fin proximate the conductive gate.

According to a further aspect of the present disclosure, a fin field effect transistor (FinFET) is described. In one configuration, the FinFET includes a means for applying stress to the gate stack. The stress applying means may be the compressive conductive gate stressor, 812, the stressor material 912, 1012 and/or 1112. In another aspect, the aforementioned means may be any module or any apparatus configured to perform the functions recited by the aforementioned means.

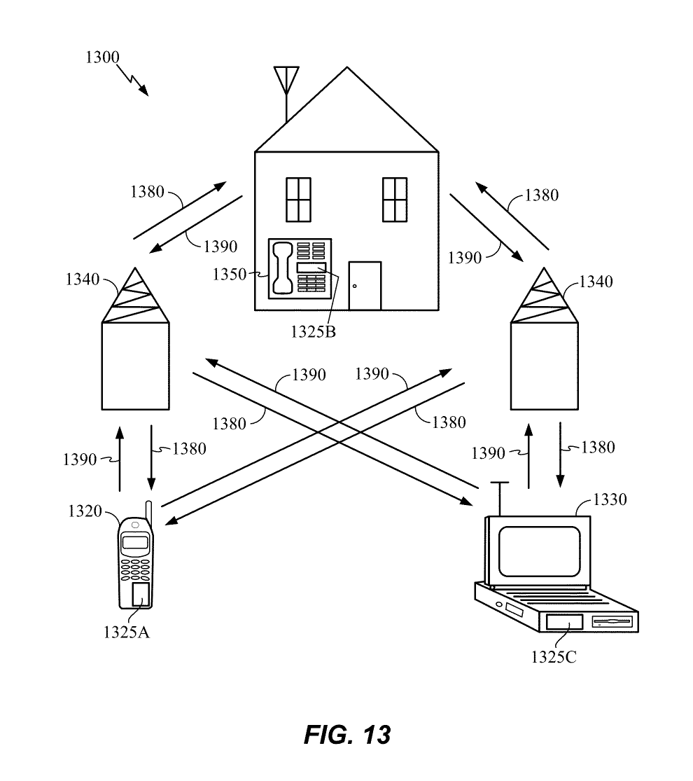

FIG. 13 is a block diagram showing an exemplary wireless communication system 1300 in which an aspect of the disclosure may be advantageously employed. For purposes of illustration, FIG. 13 shows three remote units 1320, 1330, and 1350 and two base stations 1340. It will be recognized that wireless communication systems may have many more remote units and base stations. Remote units 1320, 1330, and 1350 include IC devices 1325A, 1325C, and 1325B that include the disclosed FinFET devices. It will be recognized that other devices may also include the disclosed FinFET devices, such as the base stations, switching devices, and network equipment. FIG. 13 shows forward link signals 1380 from the base station 1340 to the remote units 1320, 1330, and 1350 and reverse link signals 1390 from the remote units 1320, 1330, and 1350 to base stations 1340.

In FIG. 13, remote unit 1320 is shown as a mobile telephone, remote unit 1330 is shown as a portable computer, and remote unit 1350 is shown as a fixed location remote unit in a wireless local loop system. For example, the remote units may be mobile phones, hand-held personal communication systems (PCS) units, portable data units such as personal data assistants, GPS enabled devices, navigation devices, set top boxes, music players, video players, entertainment units, fixed location data units such as meter reading equipment, or other devices that store or retrieve data or computer instructions, or combinations thereof. Although FIG. 13 illustrates remote units according to the aspects of the disclosure, the disclosure is not limited to these exemplary illustrated units. Aspects of the disclosure may be suitably employed in many devices, which include the disclosed FinFET devices.

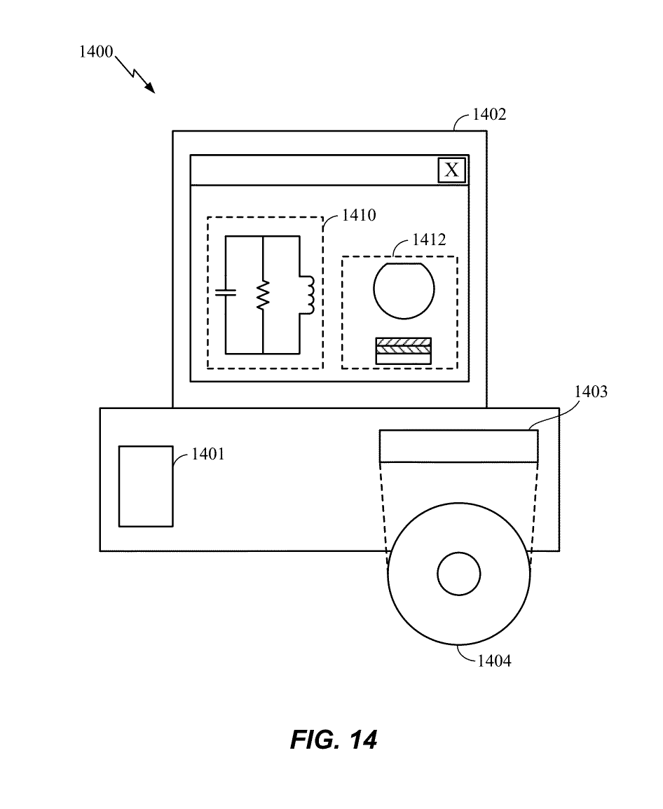

FIG. 14 is a block diagram illustrating a design workstation used for circuit, layout, and logic design of a semiconductor component, such as the FinFET devices disclosed above. A design workstation 1400 includes a hard disk 1401 containing operating system software, support files, and design software such as Cadence or OrCAD. The design workstation 1400 also includes a display 1402 to facilitate design of a circuit 1410 or a semiconductor component 1412 such as a FinFET device. A storage medium 1404 is provided for tangibly storing the design of the circuit 1410 or the semiconductor component 1412. The design of the circuit 1410 or the semiconductor component 1412 may be stored on the storage medium 1404 in a file format such as GDSII or GERBER. The storage medium 1404 may be a CD-ROM, DVD, hard disk, flash memory, or other appropriate device. Furthermore, the design workstation 1400 includes a drive apparatus 1403 for accepting input from or writing output to the storage medium 1404.

Data recorded on the storage medium 1404 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1404 facilitates the design of the circuit 1410 or the semiconductor component 1412 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. A method for fabricating a fin field effect transistor (FinFET) device on a semiconductor substrate, comprising:
forming a gate stack on a surface of a semiconductor fin;
depositing a dielectric layer on the semiconductor fin to be substantially coplanar with a surface of a conductive gate of the gate stack;
recessing the conductive gate to be below a level of the dielectric layer;
depositing a stressor material onto a recessed surface of the conductive gate and the dielectric layer;
confining the stressor material; and
changing a volume of the stressor material to stress the semiconductor fin proximate the conductive gate.

2. The method of claim 1, in which changing the volume comprises expanding the stressor material by annealing the stressor material to compress the conductive gate.

3. The method of claim 1, in which changing the volume comprises expanding the stressor material by silicidation or oxidation of the stressor material to compress the conductive gate.

4. The method of claim 1, in which changing the volume comprises increasing the volume to compressively stress the semiconductor fin in an N-channel FinFET along a height of the semiconductor fin.

5. The method of claim 1, in which changing the volume comprises decreasing the volume to provide tensile stress on the semiconductor fin in a P-channel FinFET along a height of the semiconductor fin.

6. The method of claim 1, in which the stressor material is tungsten (W), titanium (Ti), cobalt (Co), silicon (Si), nickel (Ni) or perovskite (CaTiO₃).

7. The method of claim 1, further comprising integrating the FinFET device into a mobile phone, a set top box, a music player, a video player, an entertainment unit, a navigation device, a computer, a hand-held personal communication systems (PCS) unit, a portable data unit, and/or a fixed location data unit.

8. A fin field effect transistor (FinFET), comprising:
a gate stack on a surface of a semiconductor fin;
a capping material; and
a stressor material confined by the capping material to a region proximate the gate stack to provide stress on the semiconductor fin proximate the gate stack.

9. The FinFET of claim 8, in which the stressor material provides compressive stress on the semiconductor fin in an N-channel FinFET along a height of the semiconductor fin.

10. The FinFET of claim 8, in which the stressor material provides tensile stress on the semiconductor fin in a P-channel FinFET along a height of the semiconductor fin.

11. The FinFET of claim 8, in which the stressor material comprises CaTiO3and the capping material is a dielectric.

12. The FinFET of claim 8, in which the stressor material comprises W, Ti, Co, Ni and the capping material is polysilicon.

13. The FinFET of claim 8, in which the stressor material comprises polysilicon and the capping material is an oxide.

14. The FinFET of claim 8, in which the stressor material provides stress by changing a volume of the stressor material.

15. The FinFET of claim 14, in which changing the volume comprises expanding the stressor material by annealing, silicidation or oxidation to compress the gate stack.

16. The FinFET of claim 8 integrated into a mobile phone, a set top box, a music player, a video player, an entertainment unit, a navigation device, a computer, a hand-held personal communication systems (PCS) unit, a portable data unit, and/or a fixed location data unit.

17. A fin field effect transistor (FinFET), comprising:
a gate stack on a surface of a semiconductor fin;
a capping material; and
means for applying stress to the gate stack, the stress applying means confined by the capping material to a region proximate the gate stack to provide stress on the semiconductor fin proximate the gate stack.

18. The FinFET of claim 17, in which the stress applying means provides compressive stress on the semiconductor fin in an N-channel FinFET along a height of the semiconductor fin.

19. The FinFET of claim 17, in which the stress applying means provides tensile stress on the semiconductor fin in a P-channel FinFET along a height of the semiconductor fin.

20. The FinFET of claim 17, in which the stress applying means comprises CaTiO3 and the capping material is a dielectric.

21. The FinFET of claim 17, in which the stress applying means comprises W, Ti, Co, Ni and the capping material is polysilicon.

22. The FinFET of claim 17, in which the stress applying means comprises polysilicon and the capping material is an oxide.

23. The FinFET of claim 17 integrated into a mobile phone, a set top box, a music player, a video player, an entertainment unit, a navigation device, a computer, a hand-held personal communication systems (PCS) unit, a portable data unit, and/or a fixed location data unit.

24. A method for fabricating a fin field effect transistor (FinFET) device on a semiconductor substrate, comprising:
a step for forming a gate stack on a surface of a semiconductor fin;
a step for depositing a dielectric layer on the semiconductor fin to be substantially coplanar with a surface of a conductive gate of the gate stack;
a step for recessing the conductive gate to be below a level of the dielectric layer;
a step for depositing a stressor material onto a recessed surface of the conductive gate and the dielectric layer;
a step for confining the stressor material; and
a step for changing a volume of the stressor material to stress the semiconductor fin proximate the conductive gate.

25. The method of claim 24, in which the step for changing the volume comprises a step for expanding the stressor material by annealing the stressor material to compress the conductive gate.

26. The method of claim 24, in which the step for changing the volume comprises a step for expanding the stressor material by silicidation or oxidation of the stressor material to compress the conductive gate.

27. The method of claim 24, in which the step for changing the volume comprises a step for increasing the volume to compressively stress the semiconductor fin in an N-channel FinFET along a height of the semiconductor fin.

28. The method of claim 24, in which the step for changing the volume comprises a step for decreasing the volume to provide tensile stress on the semiconductor fin in a P-channel FinFET along a height of the semiconductor fin.

29. The method of claim 24, in which the stressor material comprises tungsten (W), titanium (Ti), cobalt (Co), silicon (Si), nickel (Ni) or perovskite (CaTiO₃).

30. The method of claim 24, further comprising a step of integrating the FinFET device into a mobile phone, a set top box, a music player, a video player, an entertainment unit, a navigation device, a computer, a hand-held personal communication systems (PCS) unit, a portable data unit, and/or a fixed location data unit.
